(19) United States
(12) Patent Application Publication
(10) Pub. No.: US 2023/0420269 A1
(43) Pub. Date: Dec. 28, 2023

(54) CONDUCTIVE PASTE, WIRING SUBSTRATE, LIGHT-EMITTING DEVICE,AND MANUFACTURING METHOD THEREOF

(71) Applicant: NICHIA CORPORATION, Anan-shi (JP)

(72) Inventors: Eiko MINATO, Anan-shi (JP); Masaaki KATSUMATA, Anan-shi (JP); Atsushi HOSOKAWA, Tokushima-shi (JP)

(73) Assignee: NICHIA CORPORATION, Anan-shi (JP)

(21) Appl. No.: 18/342,424

(22) Filed: Jun. 27, 2023

(30) Foreign Application Priority Data
Jun. 27, 2022 (JP) 2022-102525
Feb. 28, 2023 (JP) 2023-030068

(51) Int. Cl. H01L 21/48; H01L 33/62; H01L 23/498

(52) U.S. Cl. CPC H01L 21/4867; H01L 33/62; H01L 23/49827; H01L 2933/0066; H01L 25/0753

(57) ABSTRACT

A method of manufacturing a wiring substrate includes providing a conductive paste including metal nanoparticles, metal particles, and a resin, disposing the conductive paste on at least a first surface of an insulating base body, and forming a wiring layer by heating and pressurizing the conductive paste by using a roll press or a hard SUS plate. In the providing the conductive paste, the ratio of a mass of the metal nanoparticles to the total mass of the metal nanoparticles and the metal particles is in a range of 5 mass % to 95 mass %, and the conductive paste is heated and pressurized such that part of the wiring layer in a thickness direction is embedded in at least the first surface of the insulating base body.

### CROSS-REFERENCE TO RELATED APPLICATIONS

The present application claims priority under 35 U.S.C. § 119 to Japanese Patent Application No. 2022-102525, filed Jun. 27, 2022, and Japanese Patent Application No. 2023-030068, filed Feb. 28, 2023, the contents of which are hereby incorporated by reference in their entirety.

### BACKGROUND

### 1. Technical Field

The present disclosure relates to a conductive paste, a wiring substrate, a light-emitting device, a manufacturing method of the wiring substrate and the light-emitting device.

### 2. Description of Related Art

A wiring substrate including a wiring layer with fine particles of copper sintered on a base body has been known. For example, Japanese Patent Publication No. 2010-146734 discloses a manufacturing method of a copper film including a forming a coating film by applying a composition containing copper particles onto a base body and a disposing a shield having shape followability on an upper part of the coating film and hot-pressing the coating film to sinter the copper particles. The copper particles contain copper nanoparticles having a number mean particle diameter in a range of 1 nm to 200 nm.

### SUMMARY

An object of the present disclosure is to provide a wiring substrate in which a gap between adjacent wiring layers is easily reduced, a light-emitting device, a manufacturing method of the wiring substrate and the light-emitting device, and a conductive paste used for the wiring substrate and the light-emitting device.

A manufacturing method of a wiring substrate according to an embodiment of the present disclosure includes: providing a conductive paste including metal nanoparticles having a median diameter in a range of 10 nm to 500 nm, metal particles having a median diameter in a range of 1 μm to 10 μm, and resin; disposing the conductive paste on at least a first surface of an insulating base body having the first surface and a second surface opposite to the first surface; and forming a wiring layer by heating and pressurizing the conductive paste by using a roll press or a hard SUS plate. In the providing the conductive paste, a ratio of a mass of the metal nanoparticles to a total mass of the metal nanoparticles and the metal particles is in a range of 5 mass % to 95 mass %. In the forming the wiring layer, the conductive paste is heated and pressurized such that part of the wiring layer in a thickness direction is embedded in at least the first surface of the insulating base body.

A manufacturing method of a light-emitting device according to an embodiment of the present disclosure includes: manufacturing a wiring substrate by using a manufacturing method of a wiring substrate disclosed in an embodiment; and mounting a light-emitting component on the wiring substrate.

A wiring substrate according to an embodiment of the present disclosure includes: an insulating base body having a first surface and a second surface opposite to the first surface; and a wiring layer that is a conductive member including a sintered compact of a mixture of metal nanoparticles and metal particles having a larger particle size than the metal nanoparticles, and the sintered compact is disposed on at least the first surface of the insulating base body. An upper surface of the wiring layer has flatness, arithmetic average roughness Ra indicating the flatness is in a range of 10 nm to 100 nm, and part of the wiring layer in a thickness direction is embedded in the insulating base body.

A light-emitting device according to an embodiment of the present disclosure includes: a wiring substrate disclosed in an embodiment; and a light-emitting component to be mounted on the wiring substrate.

A conductive paste according to an embodiment of the present disclosure includes: metal nanoparticles having a median diameter in a range of 10 nm to 500 nm; metal particles having a median diameter in a range of 1 μm to 10 μm; and resin. A ratio of a mass of the metal nanoparticles to a total mass of the metal nanoparticles and the metal particles is in a range of 5 mass % to 95 mass %.

The embodiments according to the present disclosure can provide a wiring substrate in which a gap between adjacent wiring layers is easily reduced, a light-emitting device, a manufacturing method of the wiring substrate and the light-emitting device, and a conductive paste used for the wiring substrate and the light-emitting device.

### BRIEF DESCRIPTION OF THE DRAWINGS

Amore complete appreciation of embodiments of the invention and many of the attendant advantages thereof will be readily obtained by reference to the following detailed description when considered in connection with the accompanying drawings.

FIG. 1A is a schematic plan view illustrating an example of a light-emitting device according to an embodiment.

FIG. 1B is a schematic plan view illustrating an example of part of FIG. 1A.

FIG. 1C is a schematic plan view illustrating an example of part of a wiring substrate according to an embodiment.

FIG. 1D is a schematic bottom view illustrating an example of part of a wiring substrate according to an embodiment.

FIG. 2A is a schematic cutaway end view taken along a line IIA-IIA in FIG. 1B.

FIG. 2B is a schematic cutaway end view taken along a line IIB-IIB in FIG. 1B.

FIG. 2C is a schematic cutaway end view illustrating an example of an interlayer connecting portion of the wiring substrate according to an embodiment.

FIG. 3A is a flowchart illustrating a manufacturing method of the wiring substrate according to an embodiment.

FIG. 3B is a flowchart illustrating a manufacturing method of the light-emitting device according to an embodiment.

FIG. 4A is a schematic cutaway end view illustrating an example of the manufacturing method of the wiring substrate according to an embodiment.

FIG. 4B is a schematic cutaway end view illustrating an example of the manufacturing method of the wiring substrate according to an embodiment.

FIG. 4C is a schematic cutaway end view illustrating an example of the manufacturing method of the wiring substrate according to an embodiment.

FIG. 4D is a schematic cutaway end view illustrating an example of the manufacturing method of the light-emitting device according to an embodiment.

FIG. 4E is a schematic cutaway end view illustrating an example of the manufacturing method of the light-emitting device according to an embodiment.

FIG. 5A is a schematic cutaway end view illustrating an example of the manufacturing method of the wiring substrate according to an embodiment.

FIG. 5B is a schematic cutaway end view illustrating an example of the manufacturing method of the wiring substrate according to an embodiment.

FIG. 5C is a schematic cutaway end view illustrating an example of the manufacturing method of the wiring substrate according to an embodiment.

FIG. 5D is a schematic cutaway end view illustrating an example of the manufacturing method of the wiring substrate according to an embodiment.

FIG. 5E is a schematic cutaway end view illustrating an example of the manufacturing method of the wiring substrate according to an embodiment.

FIG. 5F is a schematic cutaway end view illustrating an example of the manufacturing method of the wiring substrate according to an embodiment.

FIG. 5G is a schematic cutaway end view illustrating an example of the manufacturing method of the light-emitting device according to an embodiment.

FIG. 6A is an image of a cross section of a wiring substrate in a first example.

FIG. 6B is a plan view image of the wiring substrate in the first example.

FIG. 6C is a plan view illustrating a sample when a chip shear test is performed.

FIG. 7A is an image of a cross section of a wiring substrate in a second example.

FIG. 7B is a plan view image of the wiring substrate in the second example.

FIG. 8A is an image of a cross section of a wiring substrate in a first comparative example.

FIG. 8B is a plan view image of the wiring substrate in the first comparative example.

FIG. 9 is an image of a cross section of a wiring substrate in a third example.

### DETAILED DESCRIPTION

### Embodiments

Embodiments are described below with reference to the drawings. However, the embodiments described below are examples of a conductive paste, a wiring substrate, a light-emitting device, and a manufacturing method of the wiring substrate and the light-emitting device for embodying the technical idea of the present embodiment and are not limited to the following. Unless otherwise specified, dimensions, materials, shapes, relative arrangements, or the like of components described in the embodiments are not intended to limit the scope of the present invention thereto and are merely exemplary. Sizes, positional relationships, and the like of members illustrated in the drawings can be exaggerated or simplified for clarity of description. In the embodiments, “covering” includes not only a case of covering by direct contact but also a case of indirectly covering, for example, via another member. Furthermore, “disposing” includes not only a case of disposing by direct contact but also a case of indirectly disposing, for example, via another member. Furthermore, “mounting” includes not only a case of mounting by direct contact but also a case of indirectly placing, for example, via another member.

Wiring Substrate and Light-Emitting Device

First, an example of a wiring substrate in a light-emitting device according to an embodiment is described, and then an example of the light-emitting device according to an embodiment is described.

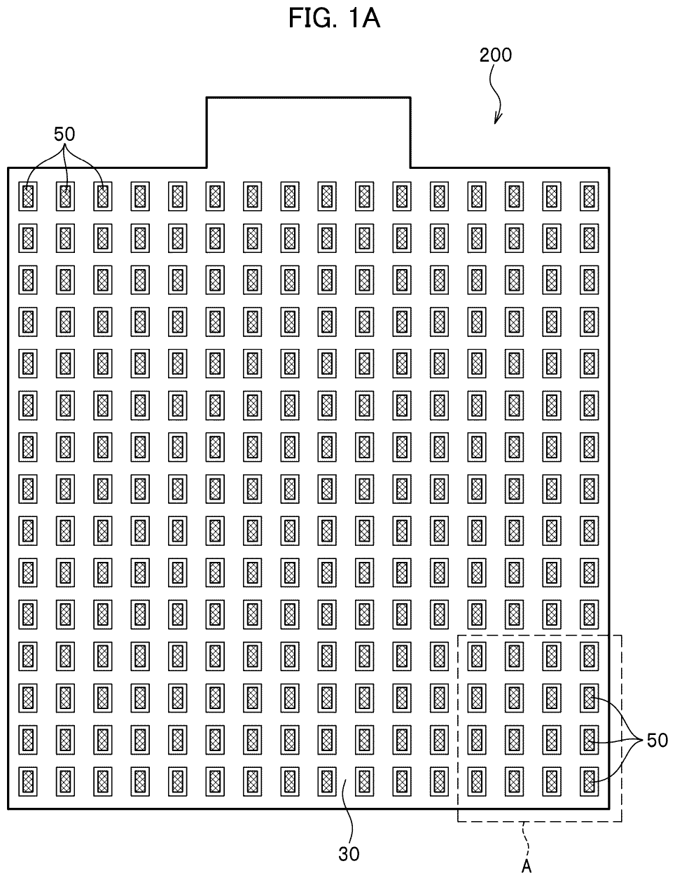

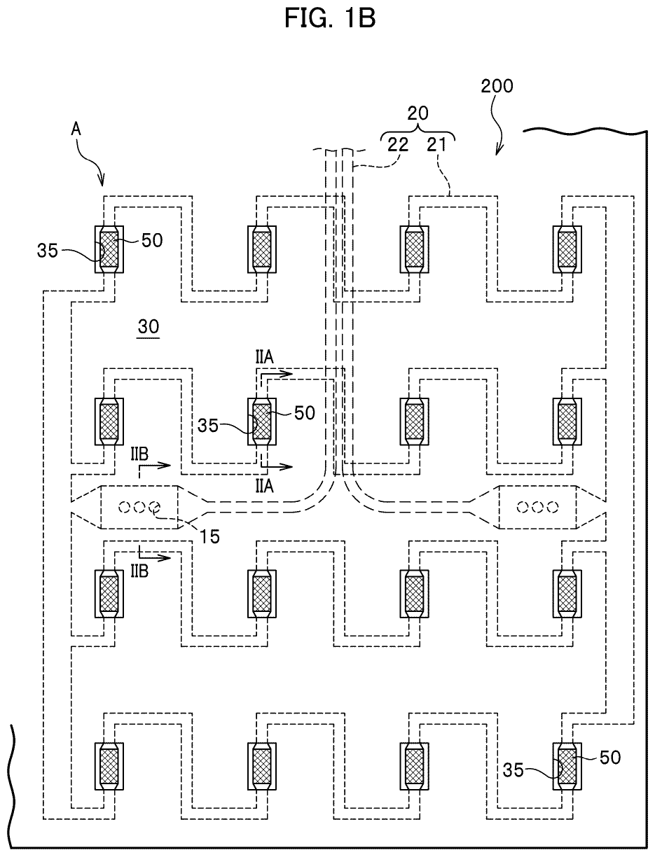

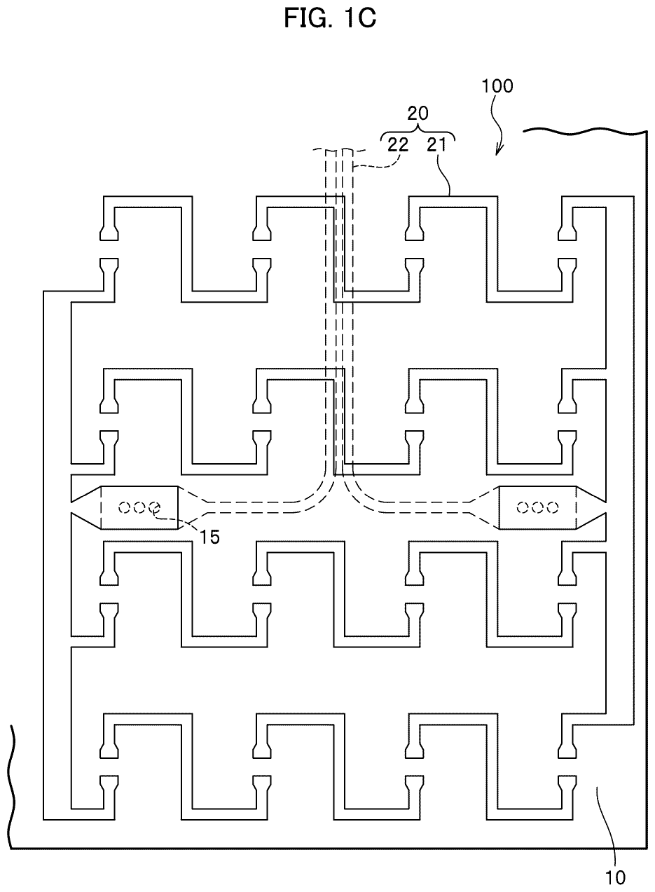

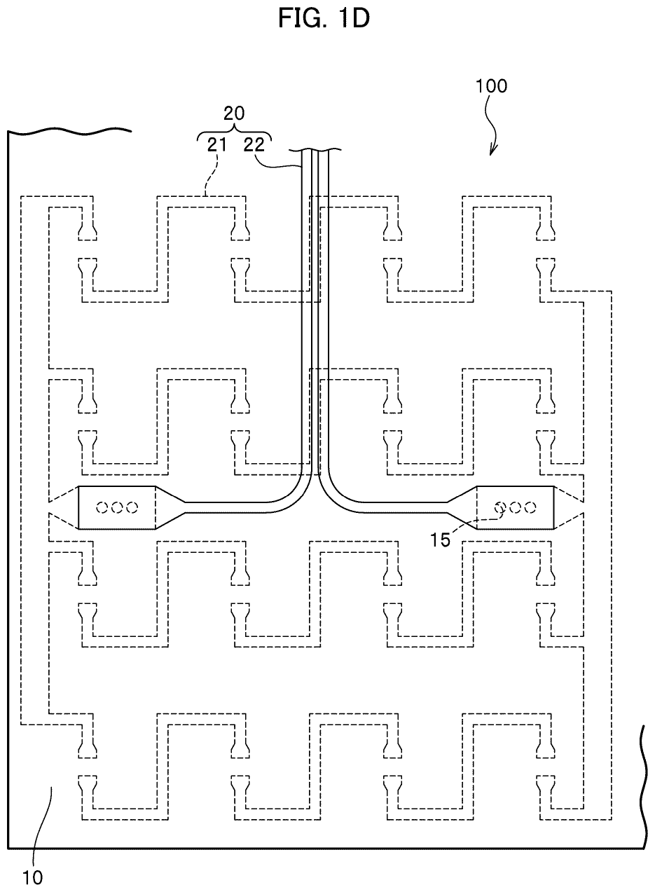

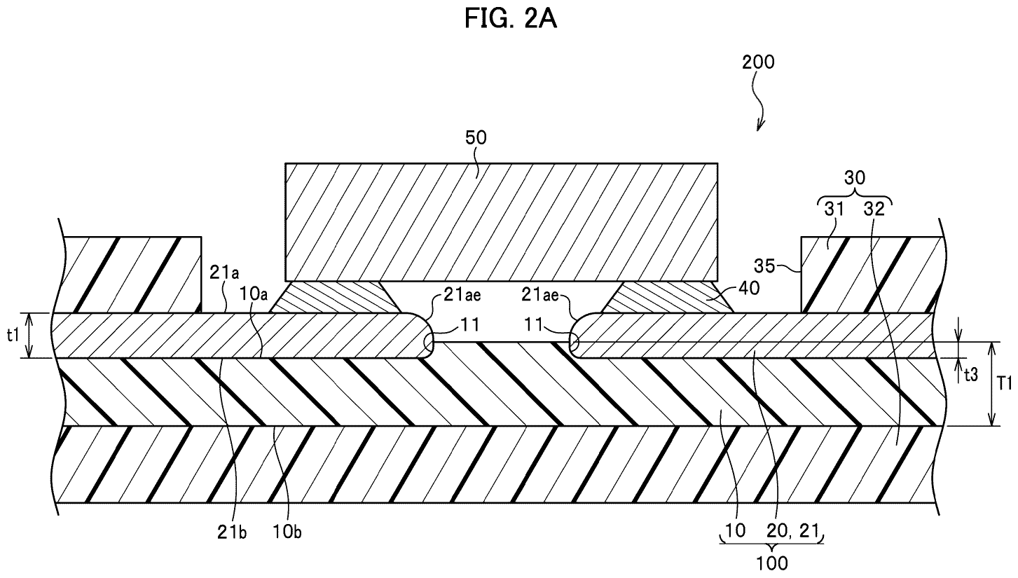

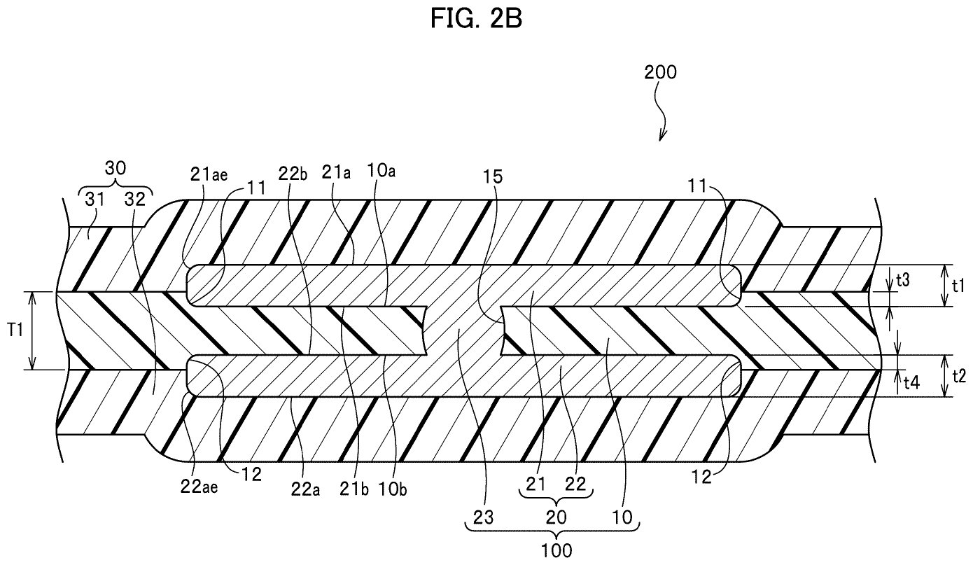

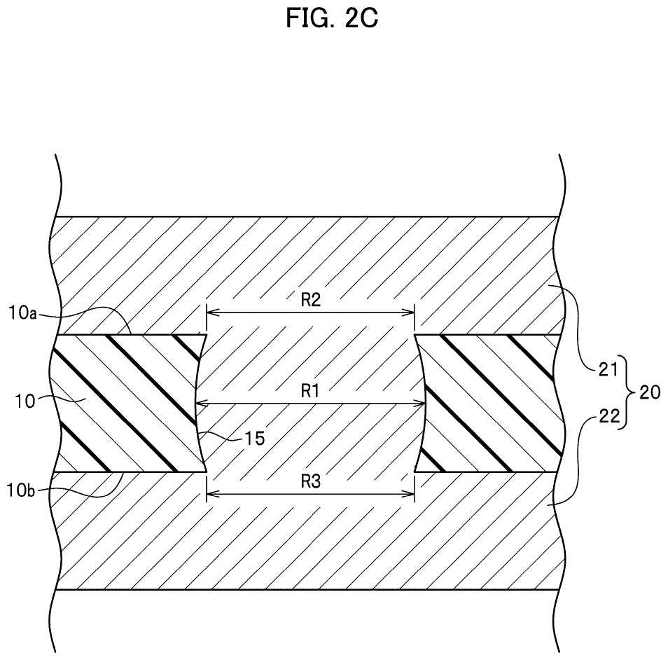

FIG. 1A is a schematic plan view illustrating an example of a light-emitting device according to an embodiment. FIG. 1B is a schematic plan view illustrating an example of part of FIG. 1A. FIG. 1C is a schematic plan view illustrating an example of part of a wiring substrate according to an embodiment. FIG. 1D is a schematic bottom view illustrating an example of part of a wiring substrate according to an embodiment. FIG. 2A is a schematic cutaway end view taken along a line IIA-IIA in FIG. 1B. FIG. 2B is a schematic cutaway end view taken along a line IIB-IIB in FIG. 1B. FIG. 2C is a schematic cutaway end view illustrating an example of an interlayer connecting portion of a wiring substrate according to an embodiment.

FIGS. 1B to 1D schematically illustrate a portion indicated by reference numeral A in FIG. 1A, and FIGS. 1C and 1D illustrate a wiring substrate from which a light-emitting component and a covering member are removed.

Wiring Substrate

A wiring substrate 100 includes an insulating base body 10 having a first surface 10a and a second surface 10b opposite to the first surface 10a and a wiring layer 20 that is a conductive member. The wiring layer 20 includes a sintered compact of a mixture of metal nanoparticles and metal particles having a larger particle size than the metal nanoparticles, and the sintered compact is disposed on at least the first surface 10a of the insulating base body 10. An upper surface of the wiring layer 20 has flatness, and arithmetic average roughness Ra indicating the flatness is in a range of 10 nm to 100 nm. In the wiring substrate 100, part of the wiring layer 20 in a thickness direction is embedded in the insulating base body 10.

The insulating base body 10 includes a through-hole 15, the wiring layer 20 is disposed on the first surface 10a of the insulating base body 10 and the second surface 10b of the insulating base body 10, a conductive member 23 is disposed in the through-hole 15, and part of the wiring layer 20 on the first surface 10a and part of the wiring layer 20 on the second surface 10b are embedded in the insulating base body 10.

Hereinafter, the wiring layer 20 on the first surface 10a of the insulating base body 10 is appropriately referred to as a first wiring layer 21, and the wiring layer 20 on the second surface 10b of the insulating base body 10 is appropriately referred to as a second wiring layer 22.

The insulating base body 10 is preferably glass epoxy, bismaleimide triazine resin, or liquid crystal polymer. When the insulating base body 10 is glass epoxy, bismaleimide triazine resin, or liquid crystal polymer, the insulating base body 10 is easily softened by heating in a manufacturing process of the wiring substrate 100, and the wiring layer 20 is easily embedded in the insulating base body 10. As the glass epoxy, plate-like glass epoxy in which one or a plurality of glass cloths with insulating resin such as epoxy resin is impregnated and cured can be used. Examples of the glass epoxy include FR-4.

The through-hole 15 penetrates the insulating base body 10. The through-hole 15 is provided at a position in the insulating base body 10 where the first wiring layer 21 of the insulating base body 10 is electrically connected to the second wiring layer 22 of the insulating base body 10. The shape of the through-hole 15 in the plan view is preferably a circle and may be an ellipse or a polygon such as a rectangle. When the shape of the through-hole 15 in the plan view is a circle, the diameter thereof is preferably in a range of 100 μm to 400 μm, for example. Setting the diameter of the through-hole 15 in this range allows the conductive member 23 to be easily disposed.

The insulating base body 10 includes a first recessed portion 11 on the first surface 10a side and a second recessed portion 12 on the second surface 10b side. The first recessed portion 11 and the second recessed portion 12 are portions formed by embedding the wiring layer 20. A thickness T1 of the insulating base body 10 in a portion where the first recessed portion 11 and the second recessed portion 12 are not formed is preferably in a range of 40 μm to 1 mm. The thickness T1 of the insulating base body 10 of 40 μm or more allows the strength of the wiring substrate 100 to be improved. On the other hand, the thickness T1 of the insulating base body 10 of 1 mm or less allows the wiring substrate 100 to be thinned. The first surface 10a of the insulating base body 10 includes a bottom surface of the first recessed portion 11. The second surface 10b of the insulating base body 10 includes a bottom surface of the second recessed portion 12. The thickness T1 is a maximum thickness in a direction perpendicular to the second surface 10b of the insulating base body 10.

The first surface 10a and the second surface 10b of the insulating base body 10 are preferably roughened. The roughened configuration improves adhesion between the insulating base body 10 and the wiring layer 20 and adhesion between the insulating base body 10 and the covering member 30. The roughening can be performed by, for example, etching, polishing, a method using a mold, or the like. The roughening can be performed such that the surface roughness Ra (arithmetic average roughness) is in a range of 1 μm to 7 μm, for example. The surface roughness Ra can be a value obtained by measuring 2000 m at a speed of 200 μm/s using a stylus type step thickness meter (Alpha-Step-IQ manufactured by KLA Tencor Corporation), for example.

The first wiring layer 21 is disposed on the first surface 10a of the insulating base body 10. The second wiring layer 22 is disposed on the second surface 10b of the insulating base body 10. As will be described below, the first wiring layer 21 and the second wiring layer 22 are formed by heating and pressurizing a conductive paste including a mixture of metal nanoparticles and metal particles and sintering the mixture. Thus, the first wiring layer 21 and the second wiring layer 22 are conductive members including a sintered compact of the mixture. The sintered compact may include non-sintered metal particles in the sintered compact of the metal nanoparticles or may include sintered metal particles. That is, the metal particles may be in a state of non-sintered particles, a state of the metal particles sintered with each other, or a state of the metal particles sintered with the metal nanoparticles.

A first surface 21a of the first wiring layer 21 has flatness. This allows a light-emitting component 50 to be easily mounted. A first surface 22a of the second wiring layer 22 has flatness. The flatness means that the difference of thicknesses between the thinnest portion and the thickest portion of the wiring layer 20 is 3 μm or less, preferably 0.3 μm or less, and more preferably 0.03 μm or less.

In the forming the wiring layer 20, it is preferable that an upper surface of the formed first wiring layer 21, that is, the first surface 21a has flatness, and the difference of thicknesses between the thinnest portion and the thickest portion of the first wiring layer 21 is 3 μm or less. Similarly, in the forming the wiring layer 20, it is preferable that an upper surface of the formed second wiring layer 22, that is, the first surface 22a has flatness, and the difference of thicknesses between the thinnest portion and the thickest portion of the second wiring layer 22 is 3 μm or less.

The arithmetic average roughness Ra indicating the flatness of the first surface 21a of the first wiring layer 21 and the first surface 22a of the second wiring layer 22 is preferably in a range of 10 nm to 100 nm. The arithmetic average roughness Ra indicating the flatness is based on JIS B 0601:2013.

An end portion 21ae of the first surface 21a of the first wiring layer 21 preferably has a rounded shape. According to such a configuration, when the first wiring layer 21 is covered with a first covering member 31, the first covering member 31 becomes thick at the end portion 21ae. This allows the color of the end portion 21ae to be less likely transparent and the reflectance to be increased. In the vicinity of the light-emitting component 50, the higher the reflectance is, the brighter the surface light-emitting body can be. Due to the roundness, the first covering member 31 is less likely to be damaged. Similarly, an end portion 22ae of the first surface 22a of the second wiring layer 22 preferably has a rounded shape. According to such a configuration, a second covering member 32 is less likely to be damaged.

A part of the first wiring layer 21 in the thickness direction is embedded in the insulating base body 10. That is, part of the first wiring layer 21 in the thickness direction is disposed in the first recessed portion 11 of the insulating base body 10. This improves adhesion between the first wiring layer 21 and the insulating base body 10 is improved. Furthermore, the thickness of the first wiring layer 21 exposed from the insulating base body 10 is reduced, allowing the thickness of the wiring substrate 100 to be reduced. An entire surface of a second surface 21b of the first wiring layer 21 opposite to the first surface 21a thereof is embedded in the insulating base body 10, and the first wiring layer 21 is embedded in the insulating base body 10 by a predetermined length from the second surface 21b in the thickness direction.

Furthermore, when part of the first wiring layer 21 in the thickness direction is embedded by heating and pressurizing, a wiring outer peripheral portion on which pressure is concentrated is deformed and embedded in a rounded shape.

Similarly, part of the second wiring layer 22 in the thickness direction is preferably embedded in the insulating base body 10. That is, part of the second wiring layer 22 in the thickness direction is disposed in the second recessed portion 12 of the insulating base body 10. This improves adhesion between the second wiring layer 22 and the insulating base body 10. Furthermore, the thickness of the second wiring layer 22 exposed from the insulating base body 10 is reduced, allowing the thickness of the wiring substrate 100 to be reduced. An entire surface of a second surface 22b of the second wiring layer 22 opposite to the first surface 22a is embedded in the insulating base body 10, and the second wiring layer 22 is embedded in the insulating base body 10 by a predetermined length from the second surface 22b in the thickness direction.

Furthermore, when part of the second wiring layer 22 in the thickness direction is embedded by heating and pressurizing, a wiring outer peripheral portion on which pressure is concentrated is deformed and embedded in a rounded shape.

A thickness t1 of the first wiring layer 21 is preferably in a range of 10 μm to 35 μm, and the first wiring layer 21 is preferably embedded in the insulating base body 10 by an amount in a range of 5 μm to 25 μm.

The thickness t1 of the first wiring layer 21 of 10 μm or more allows the first wiring layer 21 to be easily formed and part of the first wiring layer 21 in the thickness direction to be easily disposed in the insulating base body 10. The thickness t1 of the first wiring layer 21 is more preferably 13 μm or more and even more preferably 15 μm or more. On the other hand, the thickness t1 of the first wiring layer 21 of 35 μm or less allows the wiring substrate 100 to be thinned. The thickness t1 of the first wiring layer 21 is more preferably 30 μm or less and even more preferably 20 μm or less.

A thickness t3 of the first wiring layer 21 embedded in the insulating base body 10 of 5 μm or more further improves the adhesion between the first wiring layer 21 and the insulating base body 10. The thickness t3 of the first wiring layer 21 is more preferably 7 μm or more and even more preferably 10 μm or more. On the other hand, the thickness t3 of the first wiring layer 21 embedded in the insulating base body 10 is 25 μm or less allows the first wiring layer 21 to be easily formed and part of the first wiring layer 21 in the thickness direction to be easily disposed in the insulating base body 10. The thickness t3 of the first wiring layer 21 is more preferably 20 μm or less and even more preferably 15 m or less. The thicknesses t1 and t3 are maximum thicknesses of the first wiring layer 21 in a direction perpendicular to the second surface 21b.

Preferably, the first wiring layer 21 is embedded in the insulating base body by an amount in a range of 1/100 to 6/100 of the thickness T1 of the insulating base body 10. The first wiring layer 21 embedded in the insulating base body 10 of 1/100 or more of the thickness T1 of the insulating base body 10 further improves the adhesion between the first wiring layer 21 and the insulating base body 10. The first wiring layer 21 embedded in the insulating base body 10 is more preferably 2/100 or more of the thickness T1 of the insulating base body 10. On the other hand, the first wiring layer 21 embedded in the insulating base body 10 of 6/100 or less of the thickness T1 of the insulating base body 10 allows the first wiring layer 21 to be easily formed and part of the first wiring layer 21 in the thickness direction to be easily disposed in the insulating base body 10. The first wiring layer 21 embedded in the insulating base body 10 is more preferably 4/100 or less of the thickness T1 of the insulating base body 10.

The second wiring layer 22 preferably has the following configuration for the same reason as that of the first wiring layer 21.

A thickness t2 of the second wiring layer 22 is preferably in a range of 10 μm to m, and the second wiring layer 22 is preferably embedded in the insulating base body 10 by an amount in a range of 5 μm to 25 μm. The thickness t2 of the second wiring layer 22 is more preferably 13 μm or more and even more preferably 15 μm or more. The thickness t2 of the second wiring layer 22 is more preferably 30 μm or less and even more preferably 20 μm or less. A thickness t4 of the second wiring layers 22 embedded in the insulating base body 10 is more preferably 7 μm or more and even more preferably 10 m or more. The thickness t4 of the second wiring layers 22 embedded in the insulating base body 10 is more preferably 20 μm or less and even more preferably 15 μm or less. The thicknesses t2 and t4 are maximum thicknesses of the second wiring layer 22 in a direction perpendicular to the second surface 22b.

Preferably, the second wiring layer 22 is embedded in the insulating base body 10 by an amount in a range of 1/100 to 6/100 of the thickness T1 of the insulating base body 10. The second wiring layer 22 embedded in the insulating base body 10 is more preferably 2/100 or more of the thickness T1 of the insulating base body 10. The second wiring layer 22 embedded in the insulating base body 10 is more preferably 4/100 or less of the thickness T1 of the insulating base body 10.

The preferred ratio of the thickness of the insulating base body 10 to the thickness of the first wiring layer 21 embedded in the insulating base body 10 or the second wiring layer 22 embedded in the insulating base body 10 and the preferred numerical values of the thickness of the insulating base body 10, the thickness of the first wiring layer 21, the thickness of the second wiring layer 22, and the thicknesses of the first wiring layer 21 and the second wiring layer 22 embedded in the insulating base body 10 vary depending on the thickness, hardness, and the like of members used. Thus, these actual ratios and thicknesses do not necessarily coincide with the preferred values described above.

The conductive member 23 is disposed in the through-hole 15 and is electrically connected to the first wiring layer 21 and the second wiring layer 22. The conductive member 23 disposed in the through-hole 15 serves as an interlayer connecting portion. The conductive member 23 in the through-hole 15 is made of the same material as the first wiring layer 21 and the second wiring layer 22 and is a conductive member including a sintered compact of a mixture of metal nanoparticles and metal particles.

In the plan view of the portion of the wiring substrate 100 where the through-hole 15 is formed, a diameter R1 of a central portion of the through-hole 15 in the thickness direction is larger than a diameter R2 of the through-hole 15 formed on the first surface 10a of the insulating base body 10 and a diameter R3 of the through-hole 15 formed on the second surface 10b of the insulating base body 10. That is, in the through-hole 15 formed in the wiring substrate 100, the diameter R1 of the hole central portion in the thickness direction is larger than the diameter R2 of one hole opening portion and the diameter R3 of the other hole opening portion. The hole shape of the through-hole 15 has the diameter R1 of the hole central portion larger than the diameter R2 of the hole opening portion and the diameter R3 of the hole central portion, forming the conductive member 23 disposed in the through-hole 15 in a barrel shape. In FIG. 2C, the diameters R1, R2, and R3 are illustrated in a sectional view for the purpose of convenience. In this way, in the cross-sectional view, a width (corresponding to R1) of the hole central portion of the through-hole 15 is larger than a width (corresponding to R2) of the one hole opening portion and a width (corresponding to R3) of the other hole opening portion.

The barrel shape is formed such that the conductive member 23 disposed in the through-hole 15 is compressed at a higher density and that the diameter R1 of the hole central portion and the diameters R2 and R3 of the hole opening portions have different values. Such a shape improves adhesion between the insulating base body 10 and the conductive member 23 in the through-hole 15 and allows the conductive member 23 to be less likely to come out from the through-hole 15. This further improves the adhesion between the wiring layer 20 and the insulating base body 10. Such a shape more increases the density of, for example, Cu in the central portion of the through-hole 15, thus lowering thermal resistance and electrical resistance of the interlayer connecting portion. Furthermore, since voids are crushed and disappear during compression, voids are less likely to occur in the interlayer connecting portion.

The through-hole 15 to be formed in the wiring substrate 100 preferably has the diameter R1 of the hole central portion in the thickness direction larger than the diameter R2 of the one hole opening portion and the diameter R3 of the other hole opening portion by 3% or more. According to such a configuration, the density of Cu becomes higher in the central portion in the through-hole 15, resulting in a decrease in the thermal resistance and the electrical resistance of the interlayer connecting portion. Furthermore, voids are less likely to occur in the interlayer connecting portion. The upper limit of the size of the diameter R1 of the hole central portion with respect to the diameters R2 and R3 of the hole opening portions may be about 7.5%, for example.

The diameters R2 and R3 of the hole opening portions may be the same as the diameter R1 of the hole central portion. Even in such a configuration, when the conductive member 23 in the through-hole 15 is compressed, the density of the conductive member 23 is increased, resulting in a decrease in the thermal resistance and the electrical resistance of the interlayer connecting portion. Furthermore, since voids are crushed and disappear during compression, voids are less likely to occur in the interlayer connecting portion.

The volume resistivity of the conductive member is preferably 10 μΩ·cm or less. That is, the volume resistivity of the wiring layer 20 (that is, the first wiring layer 21 and the second wiring layer 22) and the conductive member 23 is preferably 10 μΩ·cm or less. The volume resistivity of the conductive member of 10 μΩ·cm or less allows the electrical resistance of the wiring layer 20 and the conductive member 23 to be further reduced. The volume resistivity of the conductive member is more preferably 8 μΩ·cm or less and even more preferably 6 μΩ·cm or less. The lower limit of the volume resistivity of the conductive member is not limited to particular values and is, for example, 2 μΩ·cm or more. The volume resistivity of the conductive member can be measured using Loresta GP MCP-T610 (manufactured by Mitsubishi Chemical Analytic Tech), for example.

The specific gravity of the conductive member is preferably 7.0 or more. That is, the specific gravity of the wiring layer 20 (that is, the first wiring layer 21 and the second wiring layer 22) and the conductive member 23 is preferably 7.0 or more. The specific gravity of the conductive member of 7.0 or more further improves the adhesion between the wiring layer 20, the conductive member 23 and the insulating base body 10. The specific gravity of the conductive member is more preferably 7.5 or more and even more preferably 8.0 or more. The upper limit of the specific gravity of the conductive member is not limited to particular values and is, for example, 8.8 or less. The specific gravity of the conductive member can be measured using a method described in JIS Z 8807:2012 “Method for measuring density and specific gravity of solid” (for example, a method using a specific gravity bottle), for example.

Light-Emitting Device

An example of the light-emitting device according to an embodiment is described below.

A light-emitting device 200 includes the wiring substrate 100 and the light-emitting component 50 to be mounted on the wiring substrate 100. Preferably, the light-emitting device 200 further includes the covering member 30.

The wiring substrate 100 is as described above.

The covering member 30 includes a first covering member 31 and a second covering member 32. For example, the first covering member 31 is disposed at a portion, other than the portion where the light-emitting component 50 is disposed, on the wiring substrate 100. Specifically, on the first surface 10a side of the insulating base body 10, an opening 35 is formed at a position where the light-emitting component 50 is disposed, and the first covering member 31 covers the first surface 10a of the insulating base body 10 and the first wiring layer 21. The second covering member 32 is disposed on the second surface 10b side of the insulating base body 10 to cover the second surface 10b of the insulating base body 10 and the second wiring layer 22.

The covering member 30 has insulating properties and is made of, for example, solder resist, polyimide resin, phenyl silicone resin, dimethyl silicone resin, or the like. As the solder resist, for example, general resist copolymer resin such as epoxy mixed with a solvent, an anti-foaming agent, or the like, or resist whitened by adding a filler such as titanium oxide can be used. The thicknesses of the first covering member 31 and the second covering member 32 are, for example, in a range of 10 μm to 50 μm.

The light-emitting component 50 is mounted on the first wiring layer 21 via an adhesive member 40 at the position of the opening 35 of the first covering member 31. Examples of the adhesive member 40 include solder paste. Examples of the light-emitting component 50 include a light-emitting element. Examples of the light-emitting element include a semiconductor laser element, a light-emitting diode (LED), and an organic electroluminescence element. The light-emitting component 50 may also be a known light-emitting element itself, or may also be a light-emitting component in which a known light-emitting element is mounted on a substrate, a package, or the like. That is, the light-emitting device 200 may be a device in which a light-emitting component including at least a light-emitting element is mounted on the wiring substrate 100, in addition to a device in which a light-emitting element is directly mounted on the wiring substrate 100.

Conductive Paste

An example of a conductive paste used in the manufacture of the wiring substrate according to an embodiment is described below.

The conductive paste includes, for example, metal nanoparticles having a median diameter in a range of 10 nm to 500 nm, metal particles having a median diameter in a range of 1 μm to 10 μm, and a resin. A ratio [metal nanoparticles:metal particles], which is referred to as the “compounding ratio” of the metal nanoparticles to the metal particles, is preferably in a range of [95:5] to [5:95]. This indicates that the ratio of a mass of the metal nanoparticles to the total mass of the metal nanoparticles and the metal particles is in a range of 5 mass % to 95 mass %. That is, the compounding ratio (%) of metal nanoparticles=(mass of metal nanoparticles/(mass of metal nanoparticles+mass of metal particles))×100(%), and the compounding ratio (%) of metal particles=(mass of metal particles/(mass of metal nanoparticles+mass of metal particles))×100(%).

The metal nanoparticles are nano-copper powders, for example. The metal nanoparticles are metal nanoparticles that are sintered at 300° C. or less, for example. The metal nanoparticles are preferably sintered at 150° C. or less, more preferably 120° C. or less, and even more preferably 100° C. or less. The lower limit of the temperature is not limited to particular values as long as the metal nanoparticles can be sintered and is, for example, 90° C. or more. However, the lower limit of the temperature is preferably as low as possible.

The metal nanoparticles preferably have a median diameter in a range of 10 nm to 500 nm. Such metal nanoparticles are commercially available and easily provided.

The metal nanoparticles may have a spherical shape, a flat shape, or other shapes. The flat shape means a flat shape, and is, for example, a shape having a thickness smaller than a maximum length in a plane direction.

The metal particles are, for example, copper powder having a larger particle diameter than the metal nanoparticles. The metal particles preferably have a median diameter in a range of 1 μm to 10 μm. Such metal particles are commercially available and easily provided. Mixing the metal particles with the metal nanoparticles suppresses spreading of the particles in a lateral direction, easily reducing a gap between adjacent wiring layers 20.

The median diameter is a 50% particle diameter (D50) in a volume-based particle size distribution, and specifically, refers to a particle diameter (volume median diameter) at which a volume-cumulative frequency from a small diameter side reaches 50% in a volume-based particle size distribution measured by a laser diffraction/scattering particle size distribution measurement method. In the laser diffraction/scattering particle size distribution measurement method, for example, a laser diffraction particle size distribution measuring apparatus (product name: MASTER SIZER3000 manufactured by MALVERN Instruments Ltd.) can be used for measurement.

The metal particles may have a spherical shape, a flat shape, or other shapes. However, the metal particles preferably have a flat shape. When the metal particles have a flat shape, the number of voids of the wiring layer 20 are likely to be reduced after part of the wiring layer 20 is embedded in the insulating base body 10, and the wiring layer 20 is less likely to be disconnected. Preferably, the metal particles have a flat shape, and the ratio of the thickness to the maximum length in the plane direction is in a range of 5 to 20. That is, when the maximum length in the plane direction is set to 100, the thickness is preferably in a range of 5 to 20. Such a flat shape allows the number of voids in the wiring layer 20 to be likely to be more reduced and the wiring layer 20 to be less likely to be disconnected. The thickness means a maximum thickness in a direction perpendicular to the plane direction.

Commercially available metal nanoparticles and metal particles may be used. Examples of the metal nanoparticle that can be used include CH-0200L1 (spherical) and CH-0200DP (flat) manufactured by Mitsui Mining & Smelting Co., Ltd. Examples of the metal particle that can be used include 1200Y (spherical) and 1200YP (flat) manufactured by Mitsui Mining & Smelting Co., Ltd. The surfaces of the metal particles are preferably not covered with aliphatic carboxylic acid molecules. This makes it easier to provide the conductive paste.

A ratio [metal nanoparticles:metal particles], which is the compounding ratio of the metal nanoparticles to the metal particles, is preferably in a range of [95:5] to [5:95]. That is, when the total mass of the metal nanoparticles and the metal particles is set to 100 mass %, the metal nanoparticles are preferably in a range of 5 mass % to 95 mass %, and the metal particles are preferably in a range of 5 mass % to 95 mass %. The metal nanoparticles of 5 mass % or more allows the mixture of the metal nanoparticles and the metal particles to be easily sintered. The metal nanoparticles are more preferably 25 mass % or more. The metal nanoparticles are even more preferably 60 mass % or more and still further preferably 70 mass % or more. When the metal nanoparticles are set to 60 mass % or more, the metal nanoparticles can be filled between the metal particles at a high density, and the resistance can be reduced by sintering. On the other hand, the metal nanoparticles of 95 mass % or less further suppresses the spreading of the particles in the lateral direction, more easily reducing a gap between adjacent wiring layers 20. The metal nanoparticles are more preferably 87 mass % or less and even more preferably 85 mass % or less. The metal particles of 5 mass % or more further suppresses the spreading of the particles in the lateral direction, more easily reducing a gap between adjacent wiring layers 20. On the other hand, the metal particles of 95 mass % or less allows the mixture to be easily sintered. More preferably, the metal particles are 75 mass % or less. The [metal nanoparticles:metal particles] is preferably in a range of [85:15] to [25:75], more preferably in a range of [83:17] to [77:23], further preferably [80:20]. That is, the compounding ratio of a mass of the metal nanoparticles to the total mass of the metal nanoparticles and the metal particles is preferably in a range of 25 mass % to 85 mass %, more preferably in a range of 77 mass % to 83 mass %, even more preferably 80 mass %.

The content of the resin is preferably in a range of 0.2 mass % to 30 mass % with respect to the total mass of the conductive paste. The content of the resin of 0.2 mass % or more increases the viscosity of the conductive paste, easily forms the wiring layer 20, and further improves the adhesion between the wiring layer 20 and the insulating base body 10. On the other hand, the content of the resin of 30 mass % or less allows the mixture to be more easily sintered. Examples of the resin include thermosetting resin such as epoxy resin, silicone resin, phenol resin, polyimide resin, polyurethane resin, melamine resin, and urea resin and thermoplastic resin such as polyvinyl pyrrolidone resin, polyvinyl alcohol resin, polyethylene glycol resin, and polyamide resin, and specific examples thereof include S-LEC (registered trade name) SV-26 manufactured by Sekisui Chemical Co., Ltd. The resin may be of the same system as the insulating base body 10.

The conductive paste preferably contains a solvent. The content of the solvent is preferably in a range of 2 mass % to 50 mass % with respect to the total mass of the conductive paste. The content of the solvent of 2 mass % or more allows the resin to be easily dissolved. On the other hand, the content of the solvent of 50 mass % or less increases the viscosity of the conductive paste and easily forms the wiring layer 20. The solvent preferably has a boiling point of 300° C. or less. The boiling point of 300° C. or less allows the solvent to be easily volatilized when the conductive paste is heated and pressurized. The boiling point of the solvent is more preferably 280° C. or less, even more preferably 260° C. or less, and still further preferably 250° C. or less. The lower limit of the boiling point is not limited to particular values and is, for example, 80° C. or more, preferably 150° C. or more, and more preferably 200° C. or more. The boiling point of 150° C. or more allows the solvent to be easily decomposed and the reducing property to be easily imparted in sintering the conductive paste.

The solvent is preferably a reducing solvent. Using a reducing solvent allows the mixture of the metal nanoparticles and the metal particles to be sintered while being reduced. This facilitates sintering of the mixture even in an air atmosphere. The reducing solvent preferably includes at least one of an alcohol, ether, ester, or acrylic solvent having a hydrocarbon group having a carbon number of at least three. Specific examples of the reducing solvent include butyl carbitol, 2-ethyl-1, 3-hexanediol, 1, 5-pentanediol, 1, 2-hexanediol, and α-terpineol, which are particularly preferred. In addition, examples of the reducing solvent include methanol, ethanol, propyl alcohol, butanol, hexanol, octanol, decanol, oleyl alcohol, ethylene glycol, diethylene glycol, triethylene glycol, tetraethylene glycol, propylene glycol, butanediol, pentanediol, hexanediol, glycerin, methylamine, ethylamine, propylamine, butylamine, hexylamine, octylamine, decylamine, oleylamine, α-terpineol, tetrahydronaphthalene, tetrahydroquinoline, tetralin, tetrahydrofuran, toluene, hexane, octane, hydrogenated pyrene, hydrogenated phenanthrene, hydrogenated wash oil, hydrogenated anthracene oil, insulating oil such as silicone oil, aldehyde, and ketone.

Manufacturing Method of Wiring Substrate and Light-Emitting Device

An example of a manufacturing method of the wiring substrate and an example of a manufacturing method of the light-emitting device according to an embodiment are described below. An example of the manufacturing method of the wiring substrate is first described, and then an example of the manufacturing method of the light-emitting device is described.

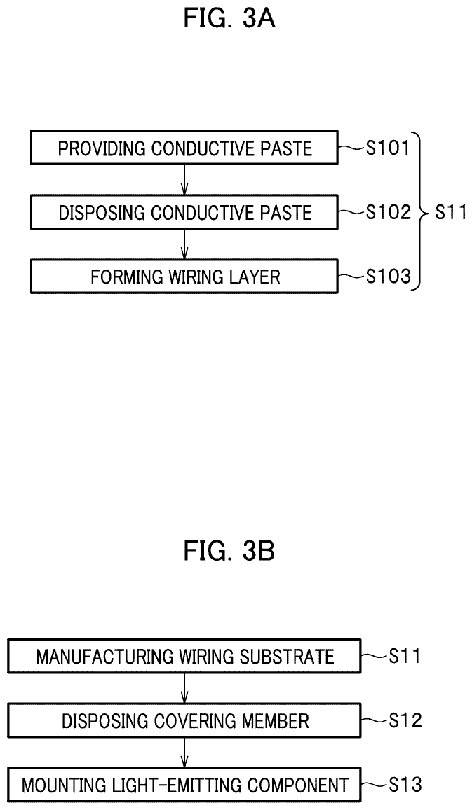

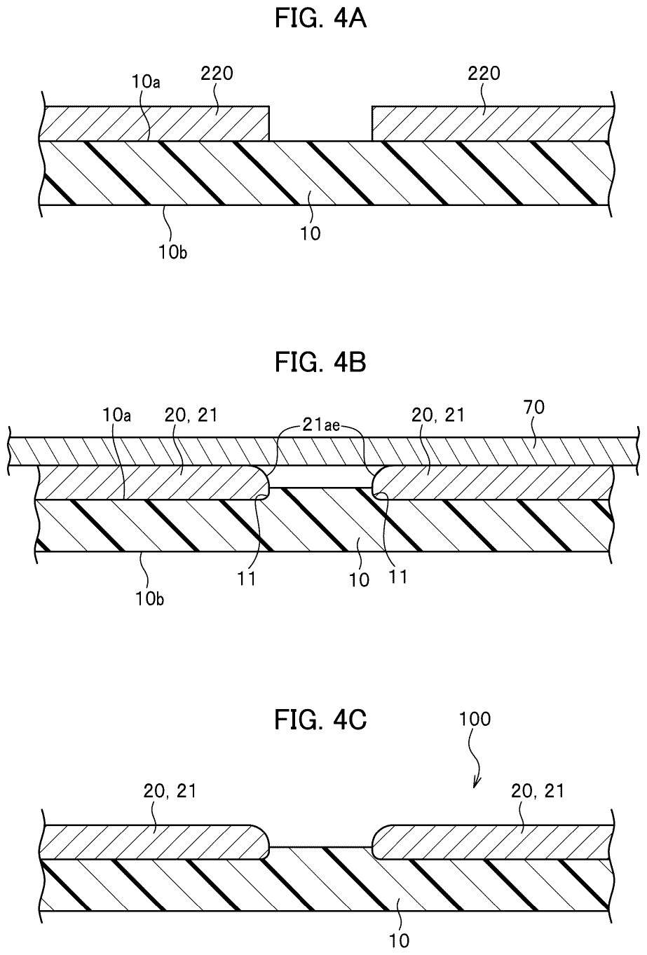

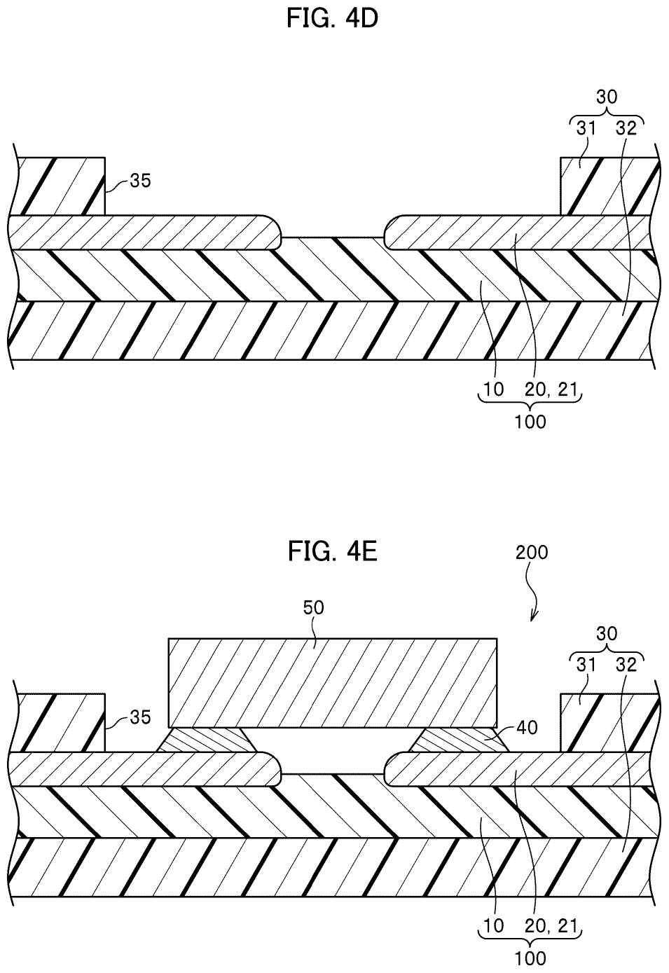

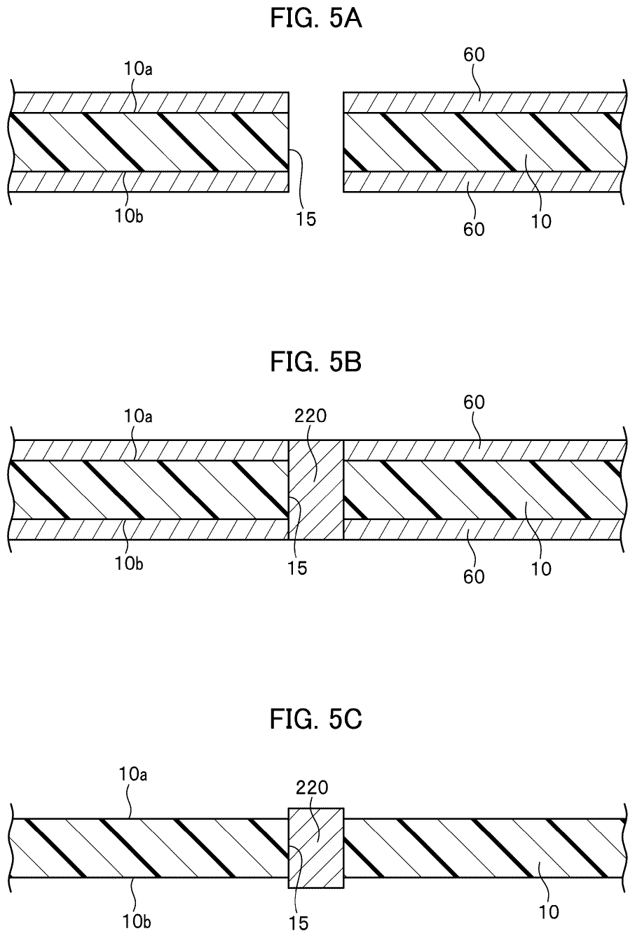

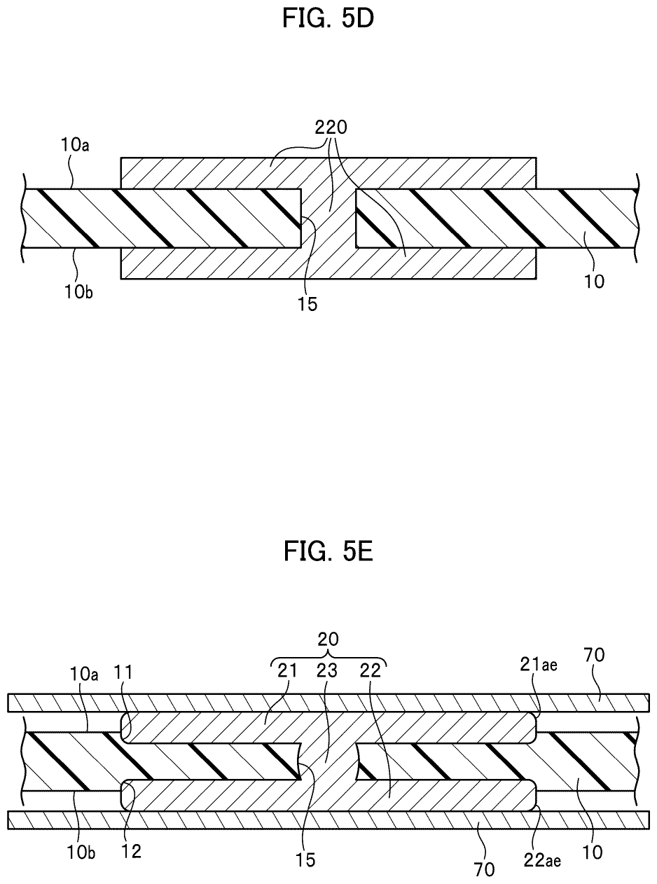

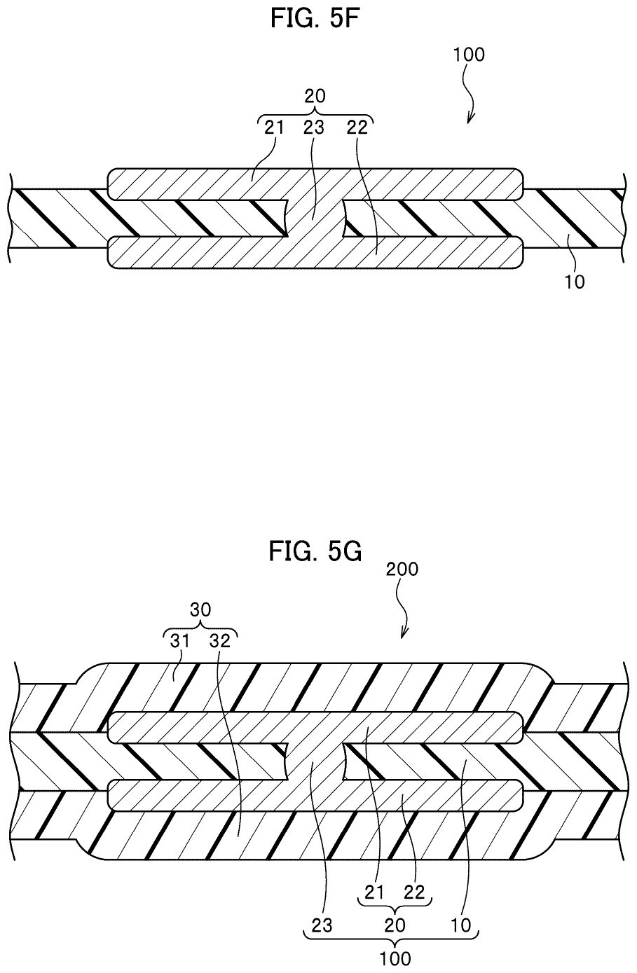

FIG. 3A is a flowchart illustrating the manufacturing method of the wiring substrate according to an embodiment. FIG. 3B is a flowchart illustrating the manufacturing method of the light-emitting device according to an embodiment. FIGS. 4A to 4C and FIGS. 5A to 5F are schematic cutaway end views illustrating an example of the manufacturing method of the wiring substrate according to an embodiment. FIGS. 4D, 4E, and 5G are schematic cutaway end views illustrating an example of the manufacturing method of the light-emitting device according to an embodiment.

Manufacturing Method of Wiring Substrate

The manufacturing method of the wiring substrate 100 includes providing a conductive paste 220 including metal nanoparticles having a median diameter in a range of 10 nm to 500 nm, metal particles having a median diameter in a range of 1 μm to 10 μm, and resin, disposing the conductive paste 220 on at least the first surface 10a of the insulating base body 10 including the first surface 10a and the second surface 10b opposite to the first surface 10a, and forming the wiring layer 20 by heating and pressurizing the conductive paste 220 by using a roll press or a hard SUS plate, wherein in the providing the conductive paste 220, the ratio of a mass of the metal nanoparticles to the total mass of the metal nanoparticles and the metal particles is preferably in a range of 5 mass % to 95 mass %, and in the forming the wiring layer 20, the conductive paste 220 is heated and pressurized such that part of the wiring layer 20 in the thickness direction is embedded in at least the first surface 10a of the insulating base body 10.

According to the manufacturing method of the wiring substrate 100, in the disposing the conductive paste 220, the insulating base body 10 includes the through-hole 15 and the conductive paste 220 is further disposed in the second surface 10b of the insulating base body 10 and the through-hole 15, and in the forming the wiring layer, the conductive paste 220 is preferably heated and pressurized such that part of the wiring layer 20 in the thickness direction is further embedded in the second surface 10b of the insulating base body 10.

Specifically, the manufacturing method of the wiring substrate 100 includes S101 of providing the conductive paste, S102 of disposing the conductive paste, and S103 of forming the wiring layer.

The material, arrangement, or the like of each member are as in the above description of the wiring substrate 100, and thus descriptions thereof are omitted as appropriate.

Providing Conductive Paste

In S101 of providing the conductive paste, the conductive paste 220 including metal nanoparticles having a median diameter in a range of 10 nm to 500 nm, metal particles having a median diameter in a range of 1 μm to 10 μm, and resin is provided.

In S101 of providing the conductive paste, the ratio of the mass of the metal nanoparticles to the total mass of the metal nanoparticles and the metal particles is in a range of 5 mass % to 95 mass %.

The conductive paste 220 is as described in the above example of the conductive paste.

Disposing Conductive Paste

In S102 of disposing the conductive paste, the conductive paste 220 is disposed on the first surface 10a of the insulating base body 10. In the present embodiment, the conductive paste 220 is also disposed on the second surface 10b of the insulating base body 10 and the through-hole 15 (see FIGS. 4A and 5A to 5D).

In S102 of disposing the conductive paste, for example, a film mask 60 such as a screen mask is first bonded to an insulating base body, and then the insulating base body 10 formed with the through-hole 15 is provided by, for example, drilling with a drill or punching. Subsequently, the through-hole 15 of the insulating base body 10 is filled with the conductive paste 220, and the conductive paste 220 is dried. Subsequently, after the film mask 60 is peeled off, the conductive paste 220 is compressed by a roll press to dispose the conductive paste 220 in the through-hole 15. Subsequently, after the conductive paste 220 is disposed on the first surface 10a of the insulating base body 10, the conductive paste 220 is dried. Subsequently, after the conductive paste 220 is disposed on the second surface 10b of the insulating base body 10, the conductive paste 220 is dried. Drying the conductive paste 220 disposed on the first surface 10a and the second surface 10b of the insulating base body 10 makes the conductive paste 220 have a desired hardness and allows subsequent pressurization to be easily performed. The drying temperature is preferably in a range of 60° C. to 100° C., for example. The drying time is preferably in a range of 3 minutes to 15 minutes, for example.

The conductive paste 220 can be disposed by, for example, screen printing using a screen mask. Alternatively, the conductive paste 220 may be disposed by metal mask printing or injection from a nozzle of a dispenser.

Forming Wiring Layer

In S103 of forming the wiring layer, the conductive paste 220 is heated and pressurized using a roll press or a hard SUS plate to form the wiring layer 20 (see FIGS. 4B, 4C, 5E, and 5F). In S103 of forming the wiring layer 20, the mixture of the metal nanoparticles and the metal particles is sintered to form a sintered compact. In S103 of forming the wiring layer 20, the resin in the conductive paste 220 is cured.

In the manufacturing method of the wiring substrate 100, adhesion between the wiring layer 20 and the insulating base body 10 is further improved by simultaneously performing the pressurization of the conductive paste 220 and the sintering of the mixture. Furthermore, the number of manufacturing steps can be reduced.

In S103 of forming the wiring layer, the conductive paste 220 is heated and pressurized using a roll press or a hard SUS plate. This makes the conductive paste 220 to be less likely to adhere to the roll press or the hard SUS plate and allows the surface state of the wiring layer 20 to be improved.

In S103 of forming the wiring layer, the conductive paste 220 is heated and pressurized such that part of the first wiring layer 21 in the thickness direction is embedded in the first surface 10a of the insulating base body 10. This forms the first recessed portion 11 in the insulating base body 10. The conductive paste 220 is preferably further heated and pressurized such that part of the second wiring layer 22 in the thickness direction is embedded in the second surface 10b of the insulating base body 10. This forms the second recessed portion 12 in the insulating base body 10. Applying heat and pressure to the conductive paste 220 allows part of the wiring layer 20 in the thickness direction to be embedded in at least the first surface 10a of the insulating base body 10 while the mixture is sintered.

In S103 of forming the wiring layer, the conductive paste 220 is preferably heated and pressurized such that the end portion 21ae of the first surface 21a of the first wiring layer 21 and the end portion 22ae of the first surface 22a of the second wiring layer 22 preferably have rounded shapes, respectively. When the conductive paste 220 is pressurized, the conductive paste 220 is pushed with a flat member, concentrating the pressure on the end portion thereof and causing the end portion 21ae and the end portion 22ae to have rounded shapes.

In S103 of forming the wiring layer, the conductive paste 220 is preferably heated and pressurized such that the first wiring layer 21 and the second wiring layer 22 are embedded in the insulating base body 10 by an amount in a range of 5 μm to 25 μm. In S103 of forming the wiring layer, the conductive paste 220 is preferably heated and pressurized such that the first wiring layer 21 and the second wiring layer 22 are embedded in the insulating base body 10 by an amount in a range of 1/100 to 6/100 of the thickness of the insulating base body 10.

In S103 of forming the wiring layer, preferably, the conductive paste 220 disposed in the through-hole 15 is also heated and pressurized. The conductive paste 220 is preferably heated and pressurized such that, in a plan view of a portion where the through-hole 15 is formed, a diameter of a central portion of the through-hole 15 in the thickness direction is larger than a diameter of the through-hole 15 formed on the first surface 10a of the insulating base body 10 and a diameter of the through-hole 15 formed on the second surface 10b of the insulating base body 10.

In S103 of forming the wiring layer, preferably, an upper surface of the formed wiring layer 20 has flatness, and the difference of thicknesses between the thinnest portion and the thickest portion of the wiring layer 20 is 3 μm or less. In S103 of forming the wiring layer, preferably, the upper surface of the formed wiring layer 20 has flatness, and the arithmetic average roughness Ra indicating the flatness is in a range of 10 nm to 100 nm. In S103 of forming the wiring layer, a gap between adjacent wiring layers 20 is preferably in a range of 30 μm to 5 cm.

The conductive paste 220 is preferably heated in a range of 190° C. to 300° C. and pressurized in a range of 2 MPa to 20 MPa. The heating temperature of 190° C. or more easily softens the insulating base body 10, and the first wiring layer 21 and the second wiring layer 22 are easily embedded in the insulating base body 10. Furthermore, the mixture is easily sintered. The heating temperature is more preferably 230° C. or more and even more preferably 250° C. or more. On the other hand, the heating temperature of 300° C. or less allows energy for heating to be reduced, which is economical. The heating temperature is more preferably 280° C. or less and even more preferably 270° C. or less.

The pressure during pressurization of 2 MPa or more allows the first wiring layer 21 and the second wiring layer 22 to be easily embedded in the insulating base body 10. The pressure during pressurization is more preferably 5 MPa or more and even more preferably 7 MPa or more. On the other hand, the pressure during pressurization of 20 Mpa or less allows energy during pressurization to be reduced, which is economical. The pressure during pressurization is more preferably 15 MPa or less and even more preferably 10 MPa or less.

The heating and pressurizing time is preferably in a range of 10 minutes to 1 hour, for example. The heating and pressurizing time of 10 minutes or more allows the first wiring layer 21 and the second wiring layer 22 to be easily embedded in the insulating base body 10. Furthermore, the mixture is easily sintered. The heating and pressurizing time is more preferably 20 minutes or more and even more preferably 30 minutes or more. On the other hand, the heating and pressurizing time of 1 hour or less allows energy for heating and pressurization to be reduced, which is economical. The heating and pressurizing time is more preferably 45 minutes or less and even more preferably 40 minutes or less. The heating and pressurization are preferably performed in an air atmosphere. Performing the heating and pressurization in the air atmosphere allows the wiring layer 20 to be easily formed without the need for, for example, shielding from the outside air. The conductive paste 220 preferably contains a reducing solvent, and the mixture of the metal nanoparticles and the metal particles is preferably sintered while being reduced by the reducing solvent. This causes the mixture of the metal nanoparticles and the metal particles to be easily sintered in the air atmosphere.

The heating and pressurizing conditions may be appropriately adjusted depending on the thicknesses of the first wiring layer 21 and the second wiring layer 22 embedded in the insulating base body 10.

In S103 of forming the wiring layer, at least the surfaces of the insulating base body 10 are preferably deformed at a temperature in a range of 190° C. to 300° C. This causes the first wiring layer 21 and the second wiring layer 22 to be easily embedded in the insulating base body 10. Furthermore, adhesion between the insulating base body 10 and the wiring layer 20 is easily improved. Being deformed here means that the surface of the insulating base body 10 is softened to cause distortion, unevenness, or the like on the surface. Specifically, the surfaces are the first surface 10a and the second surface 10b of the insulating base body 10.

After the conductive paste 220 is disposed and before the wiring layer 20 is formed, the conductive paste 220 is preferably covered with a polyimide sheet or a hard SUS plate as a peeling member 70. Subsequently, in S103 of forming the wiring layer, the conductive paste 220 is preferably pressurized via the peeling member 70. This makes the conductive paste 220 to be less likely to adhere to the peeling member 70 and allows the peeling member 70 to be easily peeled off from the wiring layer 20 after heating and pressurization. This can improve the surface state of the wiring layer 20. As the peeling member 70, a metal plate subjected to mold release treatment such as Kaniflon plating can also be used.

In the present embodiment, since a mixture of metal nanoparticles and metal particles is used for the conductive paste 220, spreading of the particles in the lateral direction is suppressed. Thus, a gap between adjacent wiring layers 20 may be set in a range of 30 μm to 5 cm and is easily set in a range of 90 μm to 200 μm, for example.

Manufacturing Method of Light-Emitting Device

The manufacturing method of the light-emitting device 200 includes manufacturing the wiring substrate 100 by using the manufacturing method of the wiring substrate 100 and mounting the light-emitting component 50 on the wiring substrate 100. The covering member 30 may be further disposed.

Specifically, the manufacturing method of light-emitting device 200 includes S11 of manufacturing the wiring substrate, S12 of disposing the covering member, and S13 of mounting the light-emitting component.

The material, arrangement, or the like of each member are as in the above description of the light-emitting device 200, and thus descriptions thereof are omitted as appropriate.

Manufacturing Wiring Substrate

In S11 of manufacturing the wiring substrate, the wiring substrate 100 is manufactured by using the manufacturing method of the wiring substrate 100 described above.

In S11 of manufacturing the wiring substrate, the wiring substrate 100 is manufactured by performing S101 to S103 described above.

Disposing Covering Member

In S12 of disposing the covering member, the covering member 30 is disposed at a portion, other than the portion where the light-emitting component 50 is disposed, on an upper surface and a lower surface of the wiring substrate 100 (see FIGS. 4D and 5G). The covering member 30 can be disposed by, for example, screen printing using a screen mask. When more accuracy is required, the covering member 30 can be disposed by exposure and development using a photosensitive resist material.

In the wiring substrate 100, since part of the wiring layer 20 in the thickness direction is embedded in the insulating base body 10, the thickness of the wiring layer 20 exposed from the insulating base body 10 can be reduced. Thus, when the covering member 30 is formed, a portion of the covering member 30 that covers the wiring layer 20 is less likely to sag, and the covering member 30 is likely to be thickly attached to the wiring layer 20 with a predetermined thickness. This can improve the reflectance of the light-emitting device 200.

Mounting Light-Emitting Component

In S13 of mounting the light-emitting component, the light-emitting component 50 is mounted on the wiring substrate 100 (see FIG. 4E).

In S13 of mounting the light-emitting component, for example, the light-emitting component 50 is mounted on the first wiring layer 21 at the position of the opening 35 of the first covering member 31 by using an adhesive member 40 such as solder paste.

The wiring substrate and the light-emitting device of the present embodiment have the following advantageous effects as compared with the related art. For example, in a wiring substrate including a wiring layer in which copper nanoparticles are sintered on a base body as in the related art, adhesion between the wiring layer and the base body is not improved. When only nanoparticles are used, the nanoparticles easily spread in a lateral direction. The nanoparticles spreading in the lateral direction generates bleeding in the wiring layer and is likely to cause a short circuit between adjacent wirings. Thus, the related art has difficulty in reducing a gap between wirings.

On the other hand, in the wiring substrate and the light-emitting device according to the present embodiment, since part of the wiring layer in the thickness direction is embedded in at least the first surface of the insulating base body, adhesion between the wiring layer and the insulating base body is excellent. The manufacturing method of the wiring substrate and the light-emitting device according to the present embodiment, which uses a mixture of metal nanoparticles and metal particles, suppresses spreading of the particles in the lateral direction and makes the particles less likely to spread in the lateral direction. This suppresses bleeding of the wiring layer and causes a short circuit to be less likely to occur between adjacent wirings. Thus, the wiring substrate and the light-emitting device according to the present embodiment easily reduces a gap between wirings. Moreover, in the wiring substrate and the light-emitting device according to the present embodiment, since the pressurization of the conductive paste and the sintering of the mixture are performed at the same time, the adhesion between the wiring layer and the insulating base body is improved.

Although the embodiments for carrying out the invention have been described above in more detail, the gist of the present invention is not limited to these descriptions and must be broadly interpreted based on the description of the scope of claims. Various modifications, variations, and the like based on these descriptions are also included within the spirit of the present invention.

For example, the wiring substrate and the light-emitting device may include no interlayer connecting portion. Furthermore, the wiring layer may be provided only on the first surface of the insulating base body. The light-emitting device may include an electronic component such as a chip resistor or a capacitor in addition to or instead of the light-emitting component.

Furthermore, the manufacturing method of the wiring substrate and the manufacturing method of the light-emitting device may each include other steps between, before, or after the steps (S101 to S103 and S11 to S13) within a range in which the steps are not adversely affected. For example, the method can include a foreign matter removal of removing foreign matter mixed during manufacturing.

### EXAMPLES

Examples and comparative examples are described below.

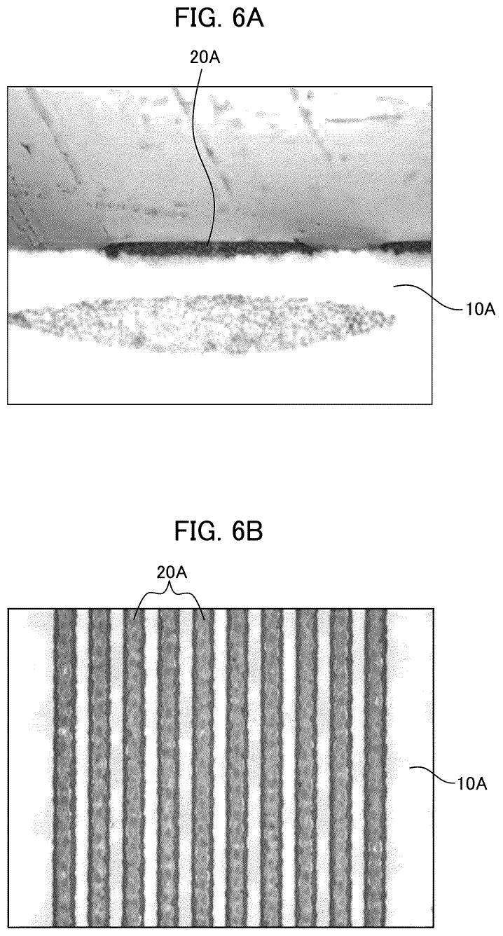

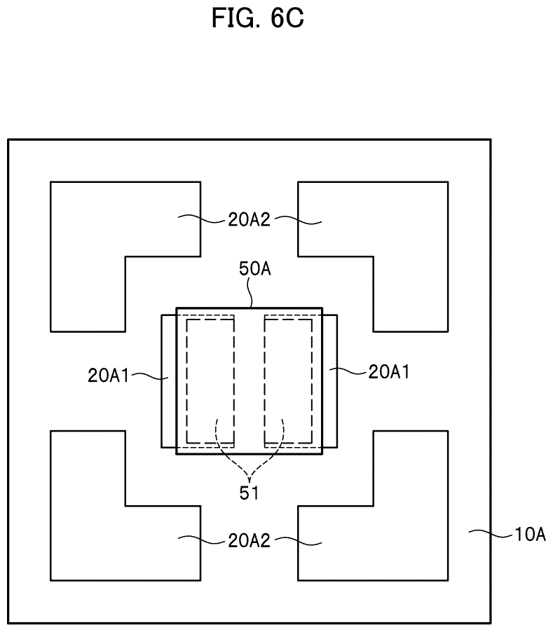

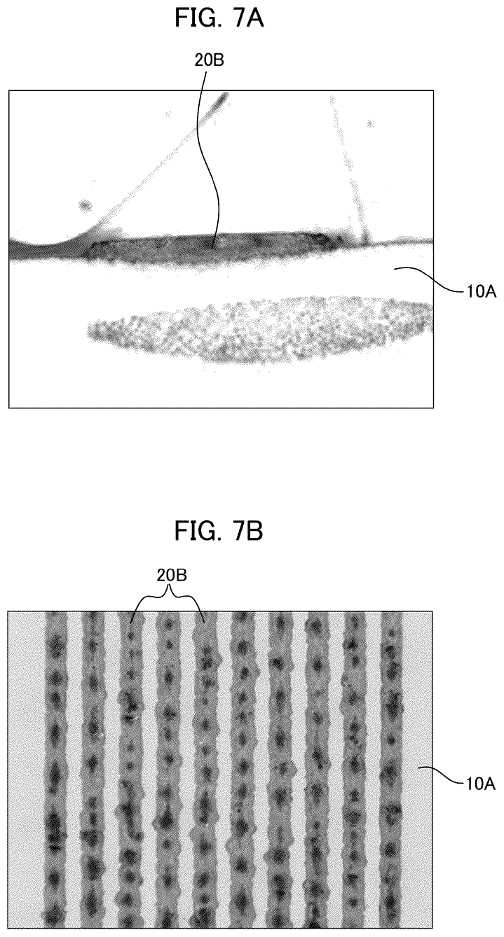

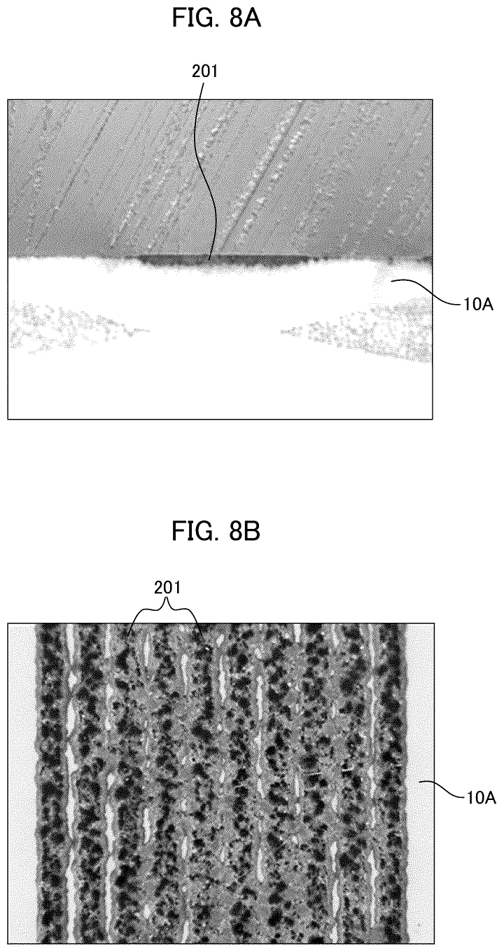

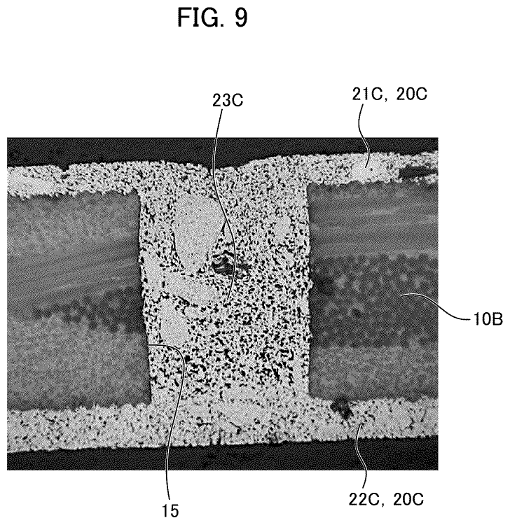

FIG. 6A is an image of a cross section of a wiring substrate in a first example. FIG. 6B is a plan view image of the wiring substrate in the first example. FIG. 6C is a plan view illustrating a sample when a chip shear test is performed. FIG. 7A is an image of a cross section of a wiring substrate in a second example. FIG. 7B is a plan view image of the wiring substrate in the second example. FIG. 8A is an image of a cross section of a wiring substrate in a first comparative example. FIG. 8B is a plan view image of the wiring substrate in the first comparative example. FIG. 9 is an image of a cross section of a wiring substrate in a third example.

The wiring substrates were produced using the following materials.
Insulating base body: FR-4 (base body thickness: 400 μm)
insulating base body: FR-4 (base body thickness: 200 μm)
Metal nanoparticles: CH-0200L1 (manufactured by Mitsui Mining & Smelting Co., Ltd,
median diameter: 210 nm, spherical)
Metal particles: 1200YP (manufactured by Mitsui Mining & Smelting Co., Ltd, median diameter: 2.98 μm, flat)
Metal particles: 1200Y (manufactured by Mitsui Mining & Smelting Co., Ltd, median diameter: 1.91 μm, spherical)
Solvent: butyl carbitol (boiling point: 230° C.)
Resin: S-LEC SV-26 (manufactured by Sekisui Chemical Co., Ltd.)
Film mask: Hitarex (registered trademark) (manufactured by Showa Denko Materials Co., Ltd., film thickness: 40 μm)

### First Example

The [metal nanoparticles:metal particles], which is the mass ratio of the metal nanoparticles and the metal particles (1200YP), is set to [50:50]. A conductive paste was provided such that solvent is 13 parts by mass and resin is 1 part by mass when a mixture of the metal nanoparticles and the metal particles (1200YP) is 100 parts by mass. Subsequently, the conductive paste was screen-printed on an upper surface of the insulating base body (base body thickness: 400 μm) by using a screen mask having a line (that is, a width of a wiring, here, a width of the conductive paste) of 0.2 mm and a space (that is, a gap between adjacent wirings, here, a gap between conductive pastes) of 0.2 mm, and was dried at 80° C. Subsequently, the conductive paste was covered with a polyimide sheet, and heat-pressed in the atmosphere at 260° C., at 9 Mpa, and for 30 minutes to produce a wiring substrate in which part of a wiring layer was embedded in the insulating base body.

As illustrated in FIGS. 6A and 6B, a wiring layer 20A has a thickness of 18 μm, and 5 μm of the thickness in the thickness direction was embedded in an insulating base body 10A. A gap between the wiring layers 20A and 20A was in a range of 90 μm to 120 μm.

As illustrated in FIG. 6C, a wiring substrate in which wiring layers 20A1 and 20A2 were formed on the insulating base body 10A under the above conditions was produced as appropriate. Three LED chips 50A each having a terminal 51 and having a size of 1 mm×1 mm were solder-mounted on a wiring layer 20A1, and were subjected to a chip shear test. Thus, adhesion between the wiring layer 20A1 disposed below the LED chip 50A and the insulating base body 10A was examined. The result was an average of 3.1 kgf. Wiring layers 20A2 at four corners were confirmed by X-ray inspection, and voids were generated at a rate of about 10% or less in all three LED chips 50A.

### Second Example

A wiring substrate was produced under the same conditions as in the first example except that 1200Y was used as metal particles.

As illustrated in FIGS. 7A and 7B, a wiring layer 20B has a thickness of 29 μm, and 9 μm of the thickness in the thickness direction was embedded in the insulating base body 10A. A gap between the wiring layers 20B and 20B was in a range of 150 μm to 180 μm. As a result of performing a chip shear test in the same manner as in the first example, the average was 2.3 kgf.

### First Comparative Example

A wiring substrate was produced under the same conditions as in the first example, except for providing a conductive paste containing 100 metal nanoparticles without using metal particles.

As illustrated in FIGS. 8A and 8B, a wiring layer 201 has a thickness of 17 μm, and 11 μm of the thickness in the thickness direction was embedded in the insulating base body 10A. Since only the metal nanoparticles were used, bleeding occurred in the wiring layer 201, and there were portions where adjacent wiring layers 201 were in contact with each other. As a result of performing a chip shear test in the same manner as in the first and second examples, the average was 3.8 kgf. Wiring layers at four corners were confirmed by X-ray inspection, and voids were generated at a rate of about 10% or more in all three LED chips 50A.

### Third Example

A conductive paste similar to that of the first example was provided. A film mask was bonded to an insulating base body (base body thickness: 200 μm), and then a through-hole having a diameter of 150 μm was formed. Subsequently, the through-hole of the insulating base body was filled with the conductive paste, and the conductive paste was dried. Subsequently, after the film mask is peeled off, the conductive paste was compressed by a roll press to dispose the conductive paste in the through-hole. Subsequently, the conductive paste was screen-printed on a first surface of the insulating base body and dried at 80° C. Subsequently, the conductive paste was screen-printed on a second surface of the insulating base body and dried at 80° C. Subsequently, the conductive paste on the first surface and the second surface of the insulating base body was covered with a polyimide sheet and hot-pressed in the atmosphere at 260° C., at 9 MPa, and for 30 minutes. In this manner, as illustrated in FIG. 9, a wiring substrate, in which a conductive member 23C was disposed in a through-hole 15 and part of a wiring layer 20C in the thickness direction was embedded in a first surface and a second surface of an insulating base body 10B, was produced.

Thicknesses of a first wiring layer 21C on a first surface side and a second wiring layer 22C on a second surface side are each 35 μm, and 10 μm of each of the thicknesses in the thickness direction was embedded in the insulating base body 10B. An interlayer connecting portion formed by disposing the conductive member 23C in the through-hole 15 has a barrel shape.

A wiring substrate and a light-emitting device according to an embodiment of the present disclosure can be used for various electronic devices.

What is claimed is:

1. A method of manufacturing a wiring substrate, the manufacturing method comprising:
providing a conductive paste including a resin, metal nanoparticles having a median diameter in a range of 10 nm to 500 nm, and metal particles having a median diameter in a range of 1 μm to 10 μm, wherein a ratio of a mass of the metal nanoparticles to a total mass of the metal nanoparticles and the metal particles is in a range of 5 mass % to 95 mass %;
disposing the conductive paste on at least a first surface of an insulating base body having the first surface and a second surface opposite to the first surface; and
forming a wiring layer by heating and pressurizing the conductive paste by using a roll press or a hard SUS plate, wherein in the forming the wiring layer, the conductive paste is heated and pressurized such that part of the wiring layer in a thickness direction is embedded in at least the first surface of the insulating base body.

2. The method according to claim 1, wherein
in the providing the conductive paste, the metal particles have a flat shape, and
the metal particles have a ratio of a thickness to a maximum length in a plane direction that is in a range of 5 to 20.

3. The method according to claim 1, wherein in the providing the conductive paste, one or more surfaces of the metal particles are not covered with an aliphatic carboxylic acid.

4. The method according to claim 1, wherein in the forming the wiring layer, the conductive paste is heated at a temperature in a range of 190° C. to 300° C. and pressurized at a pressure in a range of 2 MPa to 20 MPa.

5. The method according to claim 1, wherein in the disposing the conductive paste, the insulating base body comprises a glass epoxy, a bismaleimide triazine resin, or a liquid crystal polymer.

6. The method according to claim 1, wherein in the forming the wiring layer, at least one surface of the insulating base body is deformed at a temperature in a range of 190° C. to 300° C.

7. The method according to claim 1, wherein after the conductive paste is disposed and before the wiring layer is formed, the conductive paste is covered with a polyimide sheet or the hard SUS plate.

8. The method according to claim 1, wherein in the providing the conductive paste, the conductive paste contains a solvent having a boiling point of 300° C. or less.

9. The method according to claim 8, wherein in the providing the conductive paste, the solvent includes at least one of an alcohol, an ether, an ester, or an acrylic solvent having a hydrocarbon group having a carbon number of at least three.

10. The method according to claim 8, wherein in the providing the conductive paste, the solvent has the boiling point in a range of 150° C. to 300° C.

11. The method according to claim 1, wherein
in the disposing the conductive paste, the insulating base body includes a through-hole, and the conductive paste is further disposed on the second surface of the insulating base body and in the through-hole, and
in the forming the wiring layer, the conductive paste is heated and pressurized such that part of the wiring layer in the thickness direction is further embedded in the second surface of the insulating base body.

12. The method according to claim 11, wherein in the forming the wiring layer, the conductive paste disposed in the through-hole is also heated and pressurized.

13. The method according to claim 11, wherein in the forming the wiring layer, the conductive paste is heated and pressurized such that, in a plan view of a portion of the wiring layer where the through-hole is formed, a diameter of a central portion of the through-hole in the thickness direction is larger than a diameter of the through-hole at the first surface of the insulating base body and a diameter of the through-hole at the second surface of the insulating base body.

14. The method according to claim 1, wherein in the forming the wiring layer, the conductive paste is heated and pressurized such that the wiring layer is embedded in the insulating base body by an amount in a range of 5 μm to 25 μm.

15. The method according to claim 1, wherein in the forming the wiring layer, the conductive paste is heated and pressurized such that the wiring layer is embedded in the insulating base body by an amount in a range of 1/100 to 6/100 of a thickness of the insulating base body.

16. The method according to claim 1, wherein
in the forming the wiring layer, an upper surface of the wiring layer formed has flatness, and
a difference in thickness between the thinnest portion and the thickest portion of the wiring layer is 3 μm or less.

17. The method according to claim 1, wherein
in the forming the wiring layer, an arithmetic average roughness Ra of an upper surface of the wiring layer formed is in a range of 10 nm to 100 nm.

18. The method according to claim 1, wherein in the forming the wiring layer, a plurality of the wiring layers are formed and a distance between adjacent ones of the wiring layers is in a range of 30 μm to 5 cm.

19. A method of manufacturing a light-emitting device, the manufacturing method comprising:
manufacturing the wiring substrate using the method according to claim 1; and
mounting a light-emitting component on the wiring substrate.

20. A wiring substrate, comprising:
an insulating base body having a first surface and a second surface opposite to the first surface; and
a wiring layer that is conductive and includes a sintered compact of a mixture of metal nanoparticles and metal particles having a larger particle size than the metal nanoparticles, the sintered compact being disposed on at least the first surface of the insulating base body, wherein
an upper surface of the wiring layer has flatness,
an arithmetic average roughness Ra of the upper surface of the wiring layer is in a range of 10 nm to 100 nm, and
part of the wiring layer in a thickness direction is embedded in the insulating base body.

21. The wiring substrate according to claim 20, wherein
the insulating base body includes a through-hole,
the wiring layer is disposed on the first surface of the insulating base body, on the second surface of the insulating base body, and in the through-hole, and
part of the wiring layer on the first surface and part of the wiring layer on the second surface in the thickness direction are embedded in the insulating base body.

22. The wiring substrate according to claim 21, wherein in a plan view of a portion of the wiring layer where the through-hole is formed, a diameter of a central portion of the through-hole in the thickness direction is larger than a diameter of the through-hole at the first surface of the insulating base body and a diameter of the through-hole at the second surface of the insulating base body.

23. The wiring substrate according to claim 20, wherein
the wiring layer has a thickness in a range of 10 μm to 35 μm, and
the wiring layer is embedded in the insulating base body by an amount in a range of 5 μm to 25 μm.

24. The wiring substrate according to claim 20, wherein the conductive member has a volume resistivity that is 10 μΩ·cm or less.

25. The wiring substrate according to claim 20, wherein the conductive member has a specific gravity that is 7.0 or more.

26. A light-emitting device, comprising:
the wiring substrate according to claim 20; and
a light-emitting component to be mounted on the wiring substrate.

27. A conductive paste, comprising:
metal nanoparticles having a median diameter in a range of 10 nm to 500 nm;
metal particles having a median diameter in a range of 1 μm to 10 μm; and
a resin, wherein
a ratio of a mass of the metal nanoparticles to a total mass of the metal nanoparticles and the metal particles is in a range of 5 mass % to 95 mass %.
